(19) United States
(12) Patent Application Publication
(10) Pub. No.: US 2009/0290431 A1
(43) Pub. Date: Nov. 26, 2009

(54) NONVOLATILE MEMORY DEVICE

(75) Inventors: Se Chun Park, Seoul (KR); Duck Ju Kim, Icheon-si (KR); Chang Won Yang, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/164,010

(22) Filed: Jun. 28, 2008

(30) Foreign Application Priority Data
May 20, 2008 (KR) 2008-46597

(51) Int. Cl. G11C 16/06; G11C 7/00

(52) U.S. Cl. 365/185.25; 365/189.05; 365/203

(57) ABSTRACT

A nonvolatile memory device includes a page buffer circuit. The page buffer circuit includes a memory cell area, a first bit line select unit, and a second bit line select unit. A plurality of memory cells of the memory cell area is connected by bit lines and word lines. The first bit line select unit i s connected to one or more bit lines of the memory cell area and is configured to precharge or discharge a selected bit line in response to a control signal. The second bit line select unit is connected to the same bit line as the first bit line select unit and is configured to precharge or discharge the selected bit line simultaneously with the first bit line select unit.

### CROSS-REFERENCES TO RELATED APPLICATIONS

The present application claims priority to Korean patent application number 10-2008-0046597, filed on May 20, 2008, which is incorporated by reference in its entirety.

### BACKGROUND OF THE INVENTION

The present invention relates to nonvolatile memory devices and, more particularly, to nonvolatile memory devices which can reduce the amount of time required to precharge and discharge a bit line.

A semiconductor memory device is a memory device that is able to store data and read stored data. Semiconductor memory devices include volatile memory, which loses stored data when power is off, and nonvolatile memory, which retains stored data although power is off. Flash memory electrically erases data of cells in a group, and has been widely used in computers, memory cards, etc.

Flash memory is divided into a NOR type and a NAND type according to bit lines of a cell and the connection status of the bit lines. NOR type flash memory has a structure in which two or more cell transistors are connected in parallel to one bit line. NOR type flash memory is configured to store data using the channel hot electron method and erase data using the Fowler-Nordheim (F-N) tunneling method. NAND type flash memory has a structure in which two or more cell transistors are connected in series to one bit line. NAND type flash memory is configured to store and erase data using the F-N tunneling method. In general, NOR type flash memory is disadvantageous in regard to high integration because of high current consumption, but is advantageous in regard to high speed. NAND type flash memory is advantageous in regard to high integration because it uses a low cell current when compared with NOR type flash memory.

A method of programming the nonvolatile memory device employs an incremental step pulse programming (ISPP) method. In the ISPP method, after applying a program pulse, a program voltage is applied while increasing the program voltage to only memory cells, having a threshold voltage level lower than a verify voltage level, by a certain step. Program-inhibiting memory cells have threshold voltage distributions higher than the verify voltage level.

If a lower step voltage is set to memory cells having a specific program speed, the width of threshold voltage distributions can be narrowed. However, when a step voltage is set to be low, a program time increases. In contrast, if a step voltage is set to be high, a program time decreases, but the width of threshold voltage distributions of a memory cell is widened.

In a data read operation as well as the above program operation, an operation of precharging and discharging bit lines is very important.

FIG. 1 shows the construction of a flash memory device.

Referring to FIG. 1, a flash memory device 100 includes a memory cell array 110, a bit line select unit 120, and a latch unit 130. The flash memory device 100 includes a variety of function blocks, but they are omitted in FIG. 1 for simplicity.

The memory cell array 100 includes memory blocks BK comprised of a plurality of memory cells for storing data. Memory cells of each memory block BK are connected by bit lines BL and word lines WL. The bit lines are generally separated into even bit lines BLe and odd bit lines BLo.

An even and odd bit line pair is connected to one page buffer. The page buffer circuit generally includes the bit line select unit 120 for selecting even or odd bit lines and the latch unit 130 for latching data to be programmed and data to be read.

The bit line select unit 120 selects an even or odd bit line in response to a bit line select signal BSLe or BSLo and connects a selected bit line to a sensing node SO. When the selected bit line is connected to the sensing node SO, the bit line is precharged to a voltage level of the sensing node SO.

In order to discharge a precharged bit line, a variable voltage VIRPWR of the bit line select unit 120 is applied as 0V and a precharged bit line is connected to a bit line. The sensing node SO can be precharged to a power supply voltage in response to a precharge control signal PRECH_N.

The bit line has a structure in which all of the memory blocks BK of the memory cell array 110 are shared. Even while only a specific memory block is selected and is subject to a program or data read, bit lines of all of the memory blocks BK are selected.

Thus, as the number of the memory blocks BK increases, the length of the bit lines is also increased. Assuming that a resistance component of the bit line is ‘R’, a capacitance component of the bit line is ‘C’, and 3RC is applied, the delay time of voltage discharge or precharge of the bit line can be 3RC.

Further, if the density of the memory cell array 110 increases, the delay time is lengthened. If the number of memory blocks doubles, resistance becomes 2R, capacitance becomes 2C and, therefore, the delay time becomes 12RC.

Accordingly, if the number of memory blocks doubles, the delay time increases four times. Consequently, the performance of a chip is reduced significantly.

### BRIEF SUMMARY OF THE INVENTION

The present invention is directed toward a nonvolatile memory device in which precharge and discharge are possible across a bit line so as to reduce the amount of time to precharge and discharge the bit line of the nonvolatile memory device.

According to an aspect of the present invention, a nonvolatile memory device includes a page buffer circuit. The page buffer circuit includes a memory cell area in which a plurality of memory cells is connected by bit lines and word lines, a first bit line select unit connected to one or more bit lines of the memory cell area and configured to precharge or discharge a selected bit line in response to a control signal, and a second bit line select unit connected to the same bit line as the first bit line select unit and configured to precharge or discharge the selected bit line simultaneously with the first bit line select unit.

The page buffer circuit comprises a latch unit for programming data into a memory cell, which is connected to the second bit line select unit through a sensing node, or for reading and storing data stored in a selected memory cell.

The first and second bit line select units are connected to the memory cell area through one or more bit lines.

One or more bit lines are connected to the first bit line select unit. The first bit line select unit includes a first switching element unit, including a switching element connected between each bit line and a first node and connecting each bit line and the first node in response to a bit line select signal, a second switching element unit for precharging the first node in response to a precharge control signal, and a third switching element unit comprising a switching element connected to the each bit line and providing a discharge path according to a discharge control signal.

One or more bit lines are connected to the second bit line select unit. The second bit line select unit includes a fourth switching element unit comprising a switching element connected between each bit line and the sensing node and connecting each bit line and the sensing node in response to the bit line select signal, and a fifth switching element unit comprising a switching element connected to the each bit line and providing a discharge path according to the discharge control signal.

The second bit line select unit precharges a selected bit line to a voltage, precharged by the sensing node, in response to the precharge control signal.

The first and second bit lines select the same bit line, and precharge or discharge the selected bit line at the same time.

The latch unit includes a plurality of latch circuits connected through the sensing node, and precharge means for precharging the sensing node.

A nonvolatile memory device includes a memory cell area, first and second bit line select units connected to the memory cell area through one or more bit lines disposed over and under the memory cell area, and a latch unit for programming data into a memory cell, which is connected to the second bit line select unit through a sensing node, or for reading and storing data stored in a selected memory cell. The first and second bit line select units select the same bit line and perform a precharge or discharge operation at the same time.

### BRIEF DESCRIPTION OF THE DRAWINGS

FIG. 1 shows the construction of a flash memory device;

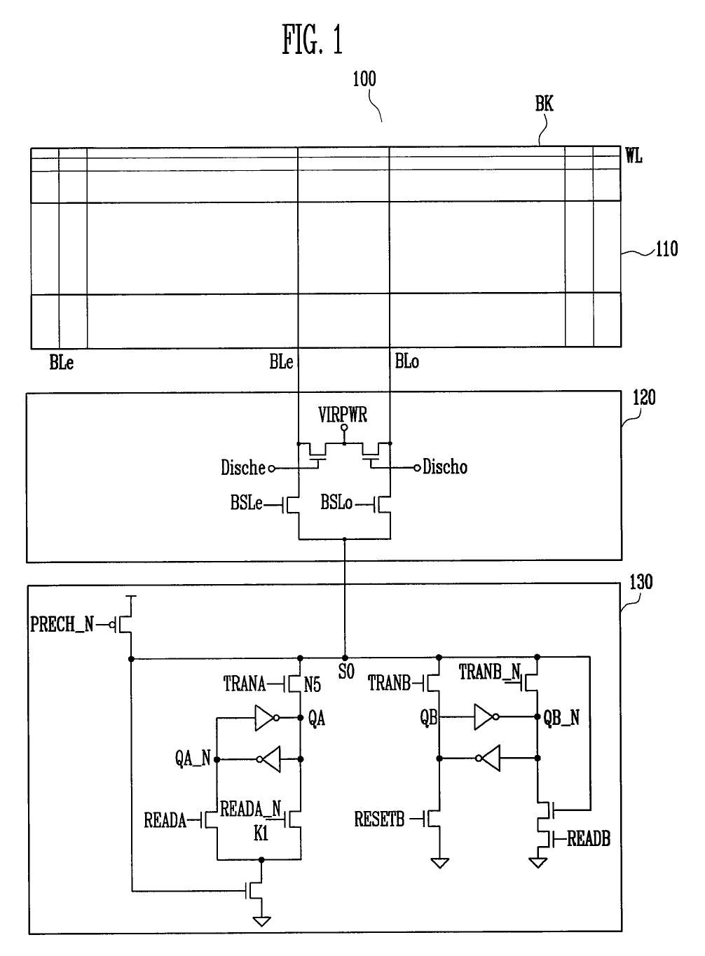

FIG. 2A is a block diagram of a nonvolatile memory device in accordance with an embodiment of the present invention; and

FIG. 2B is a detailed circuit diagram of FIG. 2A.

### DESCRIPTION OF SPECIFIC EMBODIMENT

A specific embodiment according to the present invention will be described with reference to the accompanying drawings. However, the present invention is not limited to the disclosed embodiment, but may be implemented in various ways. The embodiment is provided to complete the disclosure of the present invention and to allow those having ordinary skill in the art to understand the present invention. The present invention is defined by the scope of the claims.

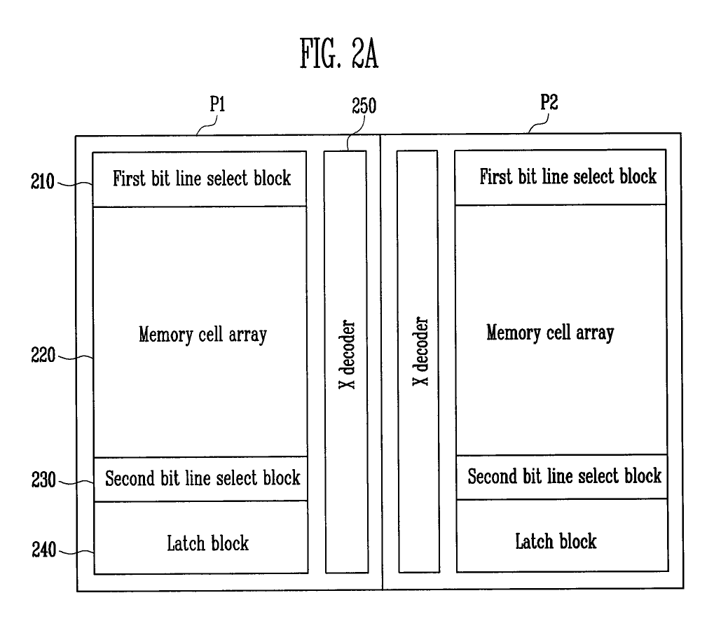

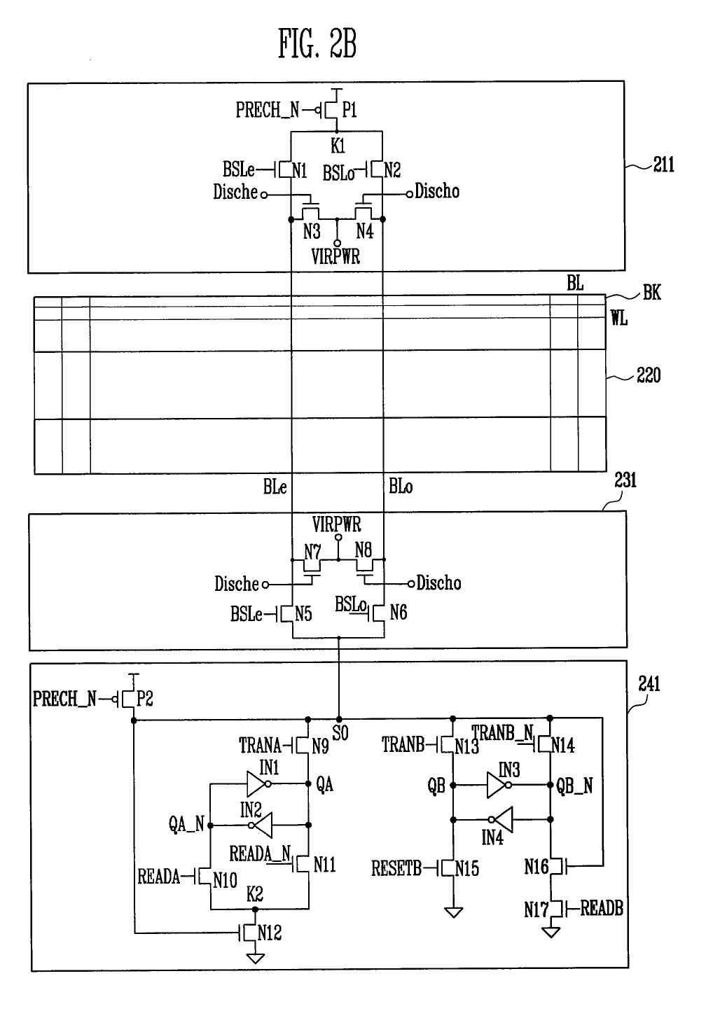

FIG. 2A is a block diagram of a nonvolatile memory device in accordance with an embodiment of the present invention. FIG. 2B is a detailed circuit diagram of FIG. 2A.

Referring to FIGS. 2A and 2B, a nonvolatile memory device in accordance with an embodiment of the present invention includes first and second planes P1, P2. Each of the planes includes a first bit line select block 210, a memory cell array 220, a second bit line select block 230, and a latch block 240.

The memory cell array 220 includes memory blocks BK, each having memory cells for storing data. The memory cells are connected to the respective memory blocks BK by bit lines and word lines. The bit lines between the memory blocks BK are commonly connected.

The first bit line select block 210 and the second bit line select block 230 respectively include first bit line select units and second bit line select units connected to one or more bit lines. The first bit line select unit and the second bit line select unit select one bit line at the same time and provide a precharge voltage or discharge voltage to the selected bit line.

The latch block 240 includes a plurality of latch units connected to the second bit line select unit of the second bit line select block 230 through a sensing node SO. Each latch unit latches data to be programmed into a memory cell or latches data read from a memory cell.

The first bit line select unit, the second bit line select unit, the memory cell array 220 and the latch unit are described in detail below.

FIG. 2B is a partial circuit diagram of the first bit line select unit 211 of the first bit line select block 210, the memory cell array 220, the second bit line select unit 231 of the second bit line select block 230, and the latch unit 241 of the latch block.

The first bit line select unit 211 includes first to fourth NMOS transistors N1 to N4, and a first PMOS transistor P1. The second bit line select unit 231 includes fifth to eighth NMOS transistors N5 to N8. The latch unit 241 includes ninth to seventeenth NMOS transistors N9 to N17, a second PMOS transistor P2, and first to fourth inverters IN1 to IN4.

The memory cell array 220 is disposed between the first bit line select unit 211 and the second bit line select unit 231. The first bit line select unit 211 and the second bit line select unit 231 are connected across the bit lines. The first bit line select unit 211 and the second bit line select unit 231 also select the same bit line at the same time.

The first PMOS transistor P1 is connected between a power supply voltage and a node K1. A precharge control signal PRECH_N is applied to the gate of the first PMOS transistor P1.

The first NMOS transistor N1 is connected between the node K1 and an even bit line. An even bit line select signal BSLe is applied to the first NMOS transistor N1. The first NMOS transistor N1 is connected between the node K1 and an odd bit line. An odd bit line select signal BSLo is applied to the gate of the second NMOS transistor N2.

The third and fourth NMOS transistors N3, N4 are connected between an even bit line and an odd bit line. A variable voltage VIRPWR is input to a connection node of the third and fourth NMOS transistors N3, N4. Discharge control signals Dische, Discho are applied to the gates of the third and fourth NMOS transistors N3, N4, respectively.

The fifth NMOS transistor N5 of the second bit line select unit 231 is connected between an even bit line and the sensing node SO. The even bit line select signal BSLe is applied to the gate of the fifth NMOS transistor N5. The sixth NMOS transistor N6 is connected between an odd bit line and the sensing node SO. The odd bit line select signal BSLo is applied to the gate of the sixth NMOS transistor N6.

The seventh and eighth NMOS transistors N7, N8 are connected between an even bit line and an odd bit line. The variable resistance VIRPWR is applied to a connection node of the seventh and eighth NMOS transistors N7, N8. The discharge control signals Dische, Discho are applied to the gates of the seventh and eighth NMOS transistors N7, N8, respectively.

The second PMOS transistor P2 is connected between a power supply voltage and the sensing node SO. The precharge control signal PRECH_N is applied to the gate of the second PMOS transistor P2.

The ninth NMOS transistor N9 is connected between the sensing node SO and a node QA. A first data transmission signal TRANA is applied to the gate of the ninth NMOS transistor N9.

The tenth NMOS transistor N10 is connected between a node QA_N and a node K2. The eleventh NMOS transistor N11 is connected between the node QA and the node K2. A read signal READA and an inverted read signal READA_N are applied to the gates of the tenth and eleventh NMOS transistors N10, N11, respectively.

The twelfth NMOS transistor N12 is connected between the node K2 and a ground node. The gate of the twelfth NMOS transistor N12 is connected to the sensing node SO. Further, the first and second inverters IN1, IN2 are connected to the latch circuit between the node QA_N and the node QA.

The thirteenth NMOS transistor N13 is connected between the sensing node SO and a node QB. A first data transmission signal TRANB is applied to the gate of the thirteenth NMOS transistor N13. The fourteenth NMOS transistor N14 is connected between the sensing node SO and a node QB_N. An inverted signal TRANB_N of the first data transmission signal is applied to the gate of the fourteenth NMOS transistor N14.

The fifteenth NMOS transistor N15 is connected between the node QB and a ground voltage. A reset control signal RESETB is applied to the gate of the fifteenth NMOS transistor N15.

The sixteenth and seventeenth NMOS transistors N16, N17 are connected in series between the node QB_N and a ground node. The gate of the sixteenth NMOS transistor N16 is connected to t he sensing node SO. A second read signal READB is applied to the gate of the seventeenth NMOS transistor N17. Further, the third and fourth inverters IN3, IN4 are connected to the latch circuit between the node QB and the node QB_N.

In the above configuration, the first bit line select unit 211 and the second bit line select unit 213 are applied with the same control signals at the same time, and therefore select a bit line at the same time. Thus, the first bit line select unit 211 and the second bit line select unit 213 are precharged to the power supply voltage received from both ends of the bit line or are discharged at both sides of the bit line at the same time.

In more detail, in the case in which the even bit line BLe is selected and precharged, first, the precharge control signal PRECH_N is input as a low level, so that the first and second PMOS transistors P1, P2 are turned on.

When the first and second PMOS transistors P1, P2 are turned on, the node K1 and the sensing node SO are precharged to a high level. Further, when the even bit line select signal BSLe is input as a high level, the first and fifth NMOS transistors N1, N5 are turned on. The high level voltage, precharged by the node K1 and the sensing node SO, is input to a bit line at both ends of the bit line, so that the bit line is precharged.

In the case in which voltage precharged by a bit line is discharged, when the variable voltage VIRPWR of 0V is applied and the discharge control signal Dische is applied as a high level, the third and seventh NMOS transistors N3, N7 are turned on, so that discharge to 0V is generated at both ends of the bit line.

Accordingly, although the number of memory blocks BK included in the memory cell array 220 increases, a precharge voltage at both ends of a bit line and a discharge path are provided, thereby shortening precharge and discharge times.

The embodiment disclosed herein has been proposed to allow a person skilled in the art to easily implement the present invention, and the person skilled in the art may implement the present invention in various ways. Therefore, the scope of the present invention is not limited by or to the embodiment as described above, and should be construed to be defined only by the appended claims and their equivalents.

What is claimed is:

1. A nonvolatile memory device:
a memory cell area comprising a plurality of memory cells connected by bit lines and word lines;
a first bit line select unit connected to one or more bit lines of the memory cell area, wherein the first bit line select unit is configured to precharge or discharge a selected bit line in response to a control signal; and
a second bit line select unit connected to the same bit line as the first bit line select unit, wherein the second bit line select unit is configured to precharge or discharge the selected bit line simultaneously with the first bit line select unit.

2. The nonvolatile memory device of claim 1, wherein the page buffer circuit comprises a latch unit for programming data into a memory cell or for reading and storing data stored in a selected memory cell, wherein the memory cell is connected to the second bit line select unit through a sensing node.

3. The nonvolatile memory device of claim 1, wherein the first and second bit line select units are connected to the memory cell area through one or more bit lines.

4. The nonvolatile memory device of claim 2, wherein:
one or more bit lines are connected to the first bit line select unit, and
the first bit line select unit comprises:
a first switching element unit comprising a first switching element connected between each bit line and a first node, wherein the first switching element unit connects each bit line and the first node in response to a bit line select signal;
a second switching element unit for precharging the first node in response to a precharge control signal; and
a third switching element unit comprising a second switching element connected to each bit line, wherein the third switching element unit provides a discharge path according to a discharge control signal.

5. The nonvolatile memory device of claim 4, wherein:
one or more bit lines are connected to the second bit line select unit, and
the second bit line select unit comprises:
a fourth switching element unit comprising a third switching element connected between each bit line and the sensing node, wherein the fourth switching element unit connects each bit line and the sensing node in response to the bit line select signal; and
a fifth switching element unit comprising a fourth switching element connected to each bit line, wherein the fifth switching element unit provides a discharge path according to the discharge control signal.

6. The nonvolatile memory device of claim 5, wherein the second bit line select unit precharges a selected bit line to a voltage, precharged by the sensing node, in response to the precharge control signal.

7. The nonvolatile memory device of claim 1, wherein the first and second bit lines select the same bit line, and precharge or discharge the selected bit line at the same time.

8. The nonvolatile memory device of claim 2, wherein the latch unit comprises:
a plurality of latch circuits connected through the sensing node, and
precharge means for precharging the sensing node.

9. A nonvolatile memory device, comprising:
a memory cell area;
first and second bit line select units connected to the memory cell area through one or more bit lines disposed over and under the memory cell area; and
a latch unit for programming data into a memory cell, or for reading and storing data stored in a selected memory cell, wherein the memory cell is connected to the second bit line select unit through a sensing node,
wherein the first and second bit line select units select the same bit line and perform a precharge or discharge operation at the same time.
